(19) United States
(12) Patent Application Publication
(10) Pub. No.: US 2026/0271255 A1
(43) Pub. Date: Sep. 10, 2026

(54) CONTROL DEVICE, CONTROL METHOD, AND PROGRAM

(71) Applicant: Panasonic Intellectual Property Management Co., Ltd., Osaka (JP)

(72) Inventors: RYO YADA, Osaka (JP); HIROKO YOSHIDA, Osaka (JP); YASUHIRO ASAIDA, Hiroshima (JP)

(21) Appl. No.: 19/539,106

(22) Filed: Feb. 13, 2026

(30) Foreign Application Priority Data
Mar. 5, 2025 (JP) 2025-034441

(51) Int. Cl. H05K 13/00; G05B 19/042; G05B 19/19; G05B 19/31; G05B 19/4069; G06F 3/06; G06V 20/59; H05K 1/181; H05K 13/02; H05K 13/04

(52) U.S. Cl. CPC H05K 13/0015; G05B 19/042; G05B 19/19; G05B 19/311; G05B 19/4069; G06F 3/0605; G06F 3/061; G06F 3/0659; G06V 20/597; H05K 1/181; H05K 13/021; H05K 13/022; H05K 13/0413

(57) ABSTRACT

Control device includes storage that stores: ideal model that mathematically expresses a behavior of mounting apparatus without considering stiffness of a floor; control model that converts a command for drive unit to change a position of mount portion to a target position into a first command value suitable for input to ideal model; and difference suppression model that outputs a second command value for reducing, to zero, a difference between the position of mount portion obtained when the first command value is input to ideal model and the position of mount portion when control unit controls drive unit on the basis of the first command value, and calculator that calculates a third command value obtained by adding the second command value to the first command value and outputs the third command value to control unit, in which control unit controls drive unit on the basis of the third command value that has been output.

### BACKGROUND

### 1. Technical Field

The present disclosure relates to a control device or the like, and for example, relates to a control device or the like that controls a mounting apparatus that mounts an electronic component on a substrate.

### 2. Description of the Related Art

Mounting apparatuses that mount electronic components on substrates are used in many factories and the like. In such a mounting apparatus, positioning control for accurately mounting the electronic component at a predetermined position is important. In order to improve the accuracy of the positioning control, for example, it is known that a technique of suppressing vibration of the mounting apparatus is effective.

For example, NPL 1 discloses a method of suppressing a gap between a model and a mounting apparatus by feeding back a difference between an output by the model that mathematically expresses the behavior of the mounting apparatus and an output by the mounting apparatus.

NPL 2 discloses a method using a model that mathematically expresses the behavior of the mounting apparatus. Specifically, modeling is performed by regarding a machine base and a leg of the mounting apparatus to be controlled as two inertial bodies. In this model, it is possible to reproduce how vibration at the leg supporting the machine base affects positioning control while the two inertial bodies affect each other.

### CITATION LIST

### Non-Patent Literature

NPL 1: Hiroshi Okashima, Nobutomo Matsunaga, “Control Using Signal Difference between Model and Actual Object”, Journal of the Institute of System Control and Information Engineers, p. 60-65, No. 2, Vol. 60, 2016
NPL 2: Akihiro Yamamoto and four others, “High-speed positioning control of linear motor drive table for suppression of vibration of machine base”, Journal of The Japan Society of Precision Engineering, p. 645-650, No. 5, Vol. 70, 2004

### SUMMARY

A control device according to an aspect of the present disclosure controls a mounting apparatus including: a drive unit that changes a position of a mount portion that mounts a second member on a first member; a control unit that controls the drive unit; a machine base that accommodates the drive unit and the control unit; and a leg that is connected to the machine base and supports the machine base with respect to a floor, the control device including a storage that stores: an ideal model that mathematically expresses a behavior of the mounting apparatus without considering stiffness of the floor; a control model that converts a command for the drive unit to change the position of the mount portion to a target position into a first command value suitable for input to the ideal model; and a difference suppression model that outputs a second command value for reducing, to zero, a difference between the position of the mount portion obtained when the first command value is input to the ideal model and the position of the mount portion when the control unit controls the drive unit on the basis of the first command value, and a calculator that calculates a third command value obtained by adding the second command value to the first command value and outputs the third command value to the control unit, in which the control unit controls the drive unit on the basis of the third command value that has been output.

A control method according to an aspect of the present disclosure is executed by a computer that controls a mounting apparatus including: a drive unit that changes a position of a mount portion that mounts a second member on a first member; a control unit that controls the drive unit; a machine base that accommodates the drive unit and the control unit; a leg that is connected to the machine base and supports the machine base with respect to a floor; and a storage that stores: an ideal model that mathematically expresses a behavior of the mounting apparatus without considering stiffness of the floor; a control model that converts a command value for the drive unit to change the position of the mount portion to a target position into a first command value suitable for input to the ideal model; and a difference suppression model that outputs a second command value for reducing, to zero, a difference between the position of the mount portion obtained when the first command value is input to the ideal model and the position of the mount portion when the control unit controls the drive unit on the basis of the first command value, the control method including a calculation step of calculating a third command value obtained by adding the second command value to the first command value and outputting the third command value to the control unit, in which the control unit controls the drive unit on the basis of the third command value that has been output.

A program according to an aspect of the present disclosure is a program for causing the computer to execute the control method.

### BRIEF DESCRIPTION OF THE DRAWINGS

FIG. 1 is a block diagram illustrating a configuration of a system including a control device according to an exemplary embodiment;

FIG. 2 is a side view illustrating an appearance of a mounting apparatus;

FIG. 3 is a perspective view illustrating the appearance of the mounting apparatus;

FIG. 4 is a diagram schematically illustrating a behavior of the mounting apparatus when stiffness of a floor is not taken into consideration;

FIG. 5 is a block diagram illustrating a control scheme for a calculator of the control device according to the exemplary embodiment to control the mounting apparatus;

FIG. 6 is a diagram for describing the control scheme of the control device illustrated in FIG. 5 by using a transfer function;

FIG. 7 is a diagram schematically illustrating a behavior of the mounting apparatus when stiffness of the floor is taken into consideration;

FIG. 8 is a flowchart illustrating an operation for tuning a control parameter for expressing a difference suppression model; and

FIG. 9 is a diagram illustrating an example of a controller when receiving an input of the control parameter in step S1 of FIG. 8.

### DETAILED DESCRIPTIONS

There is a possibility that properties of a floor (for example, the stiffness of the floor) vary depending on where a mounting apparatus is installed. The stiffness of the floor is an index indicating ease of deformation of the floor itself. That is, it is conceivable that a magnitude of vibration of the floor caused by a propagation of vibration generated when the mounting apparatus mounts an electronic component on a substrate varies depending on a difference in stiffness of the floor. However, NPL 1 and NPL 2 described above neither disclose nor suggest a method in consideration of the stiffness of the floor.

Therefore, an object of the present disclosure is to provide a control device and the like that can accurately suppress vibration of a mounting apparatus in consideration of stiffness of a floor.

### (Findings Obtained by the Inventors)

In a mounting apparatus that mounts an electronic component on a substrate, positioning control for accurately mounting the electronic component at a predetermined position is important. In order to improve the accuracy of positioning control of the mounting apparatus, for example, it is known that a technique of suppressing vibration of the mounting apparatus is effective.

For example, NPL 1 and NPL 2 disclose a method using a model that mathematically expresses a behavior of the mounting apparatus, but do not disclose or suggest a method in consideration of the stiffness of the floor. However, there is a possibility that the stiffness of the floor varies depending on where the mounting apparatus is installed. It is therefore conceivable that a magnitude of vibration of the floor caused by a propagation of vibration generated when the mounting apparatus mounts an electronic component on a substrate varies depending on a difference in stiffness of the floor.

Therefore, the inventors considered that it is necessary to consider the stiffness of the floor in order to improve the accuracy of the positioning control.

Therefore, the inventors have intensively studied whether there is a method capable of suppressing the vibration of the mounting apparatus in consideration of the stiffness of the floor. As a result, the inventors have devised a control device including an ideal model that mathematically expresses the behavior of the mounting apparatus without considering the stiffness of the floor, and a difference suppression model that calculates a difference between a response when a certain command value is input to the mounting apparatus and a response when the same certain command value is input to the ideal model. As a result, the inventors have considered that the control device can calculate a command value for the mounting apparatus in consideration of the stiffness of the floor from the difference calculated by the difference suppression model, and the accuracy of positioning control of the mounting apparatus can be improved.

Specifically, a control device according to a first aspect controls a mounting apparatus including: a drive unit that changes a position of a mount portion that mounts a second member on a first member; a control unit that controls the drive unit; a machine base that accommodates the drive unit and the control unit; and a leg that is connected to the machine base and supports the machine base with respect to a floor, the control device including a storage that stores: an ideal model that mathematically expresses a behavior of the mounting apparatus without considering stiffness of the floor; a control model that converts a command for the drive unit to change the position of the mount portion to a target position into a first command value suitable for input to the ideal model; and a difference suppression model that outputs a second command value for reducing, to zero, a difference between the position of the mount portion obtained when the first command value is input to the ideal model and the position of the mount portion when the control unit controls the drive unit on the basis of the first command value, and a calculator that calculates a third command value obtained by adding the second command value to the first command value and outputs the third command value to the control unit, in which the control unit controls the drive unit on the basis of the third command value that has been output.

As a result, since the control device includes the storage that stores the ideal model that mathematically expresses the behavior of the mounting apparatus without considering the stiffness of the floor, the control device can calculate, by using the ideal model, the position of the mount portion when only the vibration in the machine base and the leg affects the behavior of the mounting apparatus. The control device includes the storage that stores the difference suppression model that calculates the second command value for reducing, to zero, the difference between the position of the mount portion obtained when the first command value is input to the ideal model and the position of the mount portion when the control unit controls the drive unit on the basis of the first command. In other words, the difference between the position of the mount portion obtained when the first command value is input to the ideal model and the position of the mount portion when the control unit controls the drive unit on the basis of the first command is a difference obtained by the influence of the vibration of the floor generated by the propagation of vibration to the floor generated when the mounting apparatus mounts the second member on the first member. Therefore, the control device can calculate the second command value in consideration of the stiffness of the floor by using the difference suppression model. Furthermore, the control device including the calculator that outputs the third command value obtained by adding the second command value to the first command value to the control unit can cause the control unit to control the drive unit on the basis of such a third command value. Therefore, the control device can suppress the vibration of the mounting apparatus in consideration of the stiffness of the floor.

In a control device according to a second aspect which is the control device according to the first aspect, the ideal model is defined by the following equation including mass Mₕ of the mount portion, displacement amount xₕ of the mount portion, mass M_{b} of the machine base, displacement amount x_{b} of the machine base, and stiffness value Kₗ of the leg.

$$\begin{matrix}[ Equation 1 ] & \\ \frac{d}{dt} {x}_{st} = A \cdot {x}_{st} + B \cdot f \\ x = C \cdot {x}_{st} \\ {x}_{st} = [ \begin{matrix}{x}_{h} \\ \cdot \\ {x}_{h} \\ {x}_{b} \\ \cdot \\ {x}_{b}\end{matrix} ] , \\ A = [ \begin{matrix}0 & 1 & 0 & 0 \\ 0 & 0 & 0 & 0 \\ 0 & 0 & 0 & 1 \\ 0 & 0 & - {K}_{l} / {M}_{b} & 0\end{matrix} ] , \\ B = {[ \begin{matrix}0 & 1 / {M}_{h} & 0 & 1 / {M}_{b}\end{matrix} ]}^{T} , \\ C = [ \begin{matrix}1 & 0 & 1 & 0\end{matrix} ] & \end{matrix}$$

As a result, the ideal model, which is expressed by the above equation including stiffness value Kₗ of the leg, can mathematically express ideal behavior of the mounting apparatus (that is, behavior considering only the mounting apparatus without considering the vibration generated in floor). Therefore, the control device including such an ideal model can accurately suppress vibration of the mounting apparatus.

In a control device according to a third aspect which is the control device according to the first or second aspect, the second command value calculated by the calculator is a command value for suppressing vibration of the mounting apparatus caused by the stiffness of the floor.

As a result, the control device which calculates the second command value as the command value for suppressing the vibration of the mounting apparatus caused by the stiffness of the floor can suppress the vibration of the mounting apparatus in consideration of the stiffness of the floor.

A control device according to a fourth aspect is the control device according to any of the first to third aspects further including a controller that receives an input of a control parameter used to express the difference suppression model, in which the difference suppression model outputs the second command value on the basis of the control parameter having been received.

As a result, the control device can receive the input of the control parameter used to express the difference suppression model from a user via the controller. That is, after the mounting apparatus is installed in an actual site such as a factory, the control device can tune (adjust) the difference suppression model in accordance with the stiffness of the floor in a place where the mounting apparatus is installed. Therefore, the control device can more effectively suppress the vibration of the mounting apparatus after adjusting the difference suppression model suitable for the environment in which the mounting apparatus is actually used.

In a control device according to a fifth aspect which is the control device according to the fourth aspect, the control parameter is at least one of a proportional gain, an integral gain, or a derivative gain in PID control, PI control, or PD control.

As a result, even when the mounting apparatus is implemented by any one of the PID control, the PI control, or the PD control, the control device can suppress the vibration of the mounting apparatus in consideration of the stiffness of the floor.

In a control device according to a sixth aspect which is the control device according to the fourth aspect, the control parameter is a parameter related to any one of on/off control or one of PID control, PI control, or PD control to which at least one function of an anti-windup function or an output restriction function is added.

As a result, even when the mounting apparatus is implemented by any one of the on/off control or one of the PID control, the PI control, or the PD control to which the anti-windup function and the output restriction function are added, the control device can suppress the vibration of the mounting apparatus in consideration of the stiffness of the floor.

In a control device according to a seventh aspect which is the control device according to any of the first to sixth aspects, the control unit controls a current applied to the drive unit on the basis of the third command value that has been output.

As a result, as for the mounting apparatus including the drive unit current-controlled, the control device can suppress the vibration of the mounting apparatus in consideration of the stiffness of the floor.

A control method according to an eighth aspect is executed by a computer that controls a mounting apparatus including: a drive unit that changes a position of a mount portion that mounts a second member on a first member; a control unit that controls the drive unit; a machine base that accommodates the drive unit and the control unit; and a leg that is connected to the machine base and supports the machine base with respect to a floor; and a storage that stores: an ideal model that mathematically expresses a behavior of the mounting apparatus without considering stiffness of the floor; a control model that converts a command value for the drive unit to change the position of the mount portion to a target position into a first command value suitable for input to the ideal model; and a difference suppression model that outputs a second command value for reducing, to zero, a difference between the position of the mount portion obtained when the first command value is input to the ideal model and the position of the mount portion when the control unit controls the drive unit on the basis of the first command value, the control method including a calculation step of calculating a third command value obtained by adding the second command value to the first command value and outputting the third command value to the control unit, in which the control unit controls the drive unit on the basis of the third command value that has been output.

As a result, since the control device includes the storage that stores the ideal model that mathematically expresses the behavior of the mounting apparatus without considering the stiffness of the floor, the control device can calculate, by using the ideal model, the position of the mount portion when only the vibration in the machine base and the leg affects the behavior of the mounting apparatus. The control device includes the storage that stores the difference suppression model that calculates the second command value for reducing, to zero, the difference between the position of the mount portion obtained when the first command value is input to the ideal model and the position of the mount portion when the control unit controls the drive unit on the basis of the first command. In other words, the difference between the position of the mount portion obtained when the first command value is input to the ideal model and the position of the mount portion when the control unit controls the drive unit on the basis of the first command is a difference obtained by the influence of the vibration of the floor generated by the propagation of vibration to the floor generated when the mounting apparatus mounts the second member on the first member. Therefore, the control device can calculate the second command value in consideration of the stiffness of the floor by using the difference suppression model. Furthermore, the control method including a calculation step of outputting the third command value obtained by adding the second command value to the first command value to the control unit can cause the control unit to control the drive unit on the basis of such a third command value. Therefore, the control method can suppress the vibration of the mounting apparatus in consideration of the stiffness of the floor.

A program according to a ninth aspect is a program for causing the computer to execute the control method according to the eighth aspect.

As a result, the program has a similar effect to the effect of the control method described above.

### EXEMPLARY EMBODIMENT

Hereinafter, the exemplary embodiment of the present disclosure will be described in detail with reference to the drawings. Note that the exemplary embodiment to be described below shows a specific example of the present disclosure. Numerical values, constituent elements, arrangement positions and connection modes of the constituent elements, steps, order of the steps, display examples, and the like shown in the following exemplary embodiment are merely examples, and are not intended to limit the present disclosure. Furthermore, among the constituent elements in the following exemplary embodiment, constituent elements not described in the independent claims are explained as arbitrary constituent elements. In the drawings, substantially identical configurations are denoted by identical reference numerals, and overlapping descriptions may be omitted or simplified.

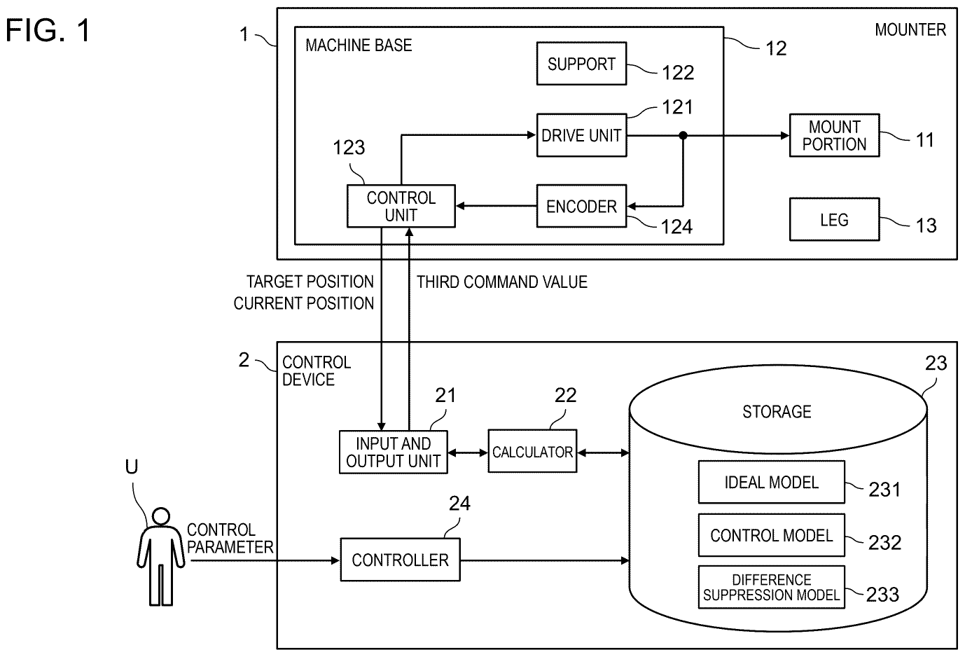

Various elements illustrated in the drawings are only schematically illustrated for the present disclosure to be understood, and a dimensional ratio, appearance, or the like in the drawings can differ from actual ones. That is, each of the drawings is a schematic diagram, and is not necessarily strictly illustrated. As a result, for example, scales and the like do not necessarily coincide in the drawings.

[Configuration] FIG. 1 is a block diagram illustrating a configuration of a system including control device 2 according to the exemplary embodiment. The system illustrated in FIG. 1 includes mounting apparatus 1 and control device 2.

Mounting apparatus 1 is, for example, an electronic component mounting apparatus that mounts an electronic component (corresponding to a second member in this specification) on a substrate (corresponding to a first member in this specification). Mounting apparatus 1 includes mount portion 11, machine base 12, and leg 13.

Mount portion 11 is, for example, a robot hand or the like that mounts the second member on the first member. For example, mount portion 11 may be a robot hand having a suction nozzle that sucks the second member by using negative pressure and mounts the second member on the first member. For example, mount portion 11 may be a robot hand that mounts the second member on the first member by pinching and lifting the second member with a claw attached to a distal end of the robot hand.

Machine base 12 is a housing that accommodates drive unit 121, support 122, control unit 123, and encoder 124.

Drive unit 121 is a motor, a linear motor, or the like that changes the position of mount portion 11. Specifically, drive unit 121 changes the position of mount portion 11 to a target position on the basis of a control signal output from control unit 123.

Support 122 is, for example, a rail that enables mount portion 11 to move and supports mount portion 11.

Control unit 123 is a device that outputs the control signal to drive unit 121 for changing the position of mount portion 11 to the target position. Specifically, control unit 123 is a servo amplifier or the like that controls a current applied to drive unit 121 on the basis of the control signal for changing the position of mount portion 11 to the target position.

Control unit 123 outputs the target position of the mount portion 11 to control device 2. Control unit 123 calculates a position (that is, a current position) of mount portion 11, a displacement amount of mount portion 11, or the like on the basis of an encoder value output from encoder 124, and outputs the position, the displacement amount, or the like to control device 2.

Encoder 124 calculates the encoder value from the displacement amount of drive unit 121 and the like, and outputs the encoder value to control unit 123.

Leg 13 is a rigid member that is connected to machine base 12 and supports machine base 12 with respect to a floor. In other words, mounting apparatus 1 is a device installed on the floor.

Control device 2 is a device that gives a command to mounting apparatus 1 for changing the position of mount portion 11 to the target position. Control device 2 includes input and output unit 21, calculator 22, storage 23, and controller 24.

Input and output unit 21 is a processing unit for communicating with mounting apparatus 1, and is, for example, a communication circuit. The communication performed by input and output unit 21 may be, for example, wireless communication or wired communication. A communication standard used for the communication is not limited.

Input and output unit 21 acquires the target position of mount portion 11 and the current position of mount portion 11 transmitted from control unit 123, and outputs the target position and the current position to calculator 22. Input and output unit 21 acquires a third command value calculated by calculator 22 and outputs the third command value to control unit 123. The third command value will be described later.

Calculator 22 is a processing unit that calculates the third command value that is a command value for changing the position of mount portion 11 to the target position. Specifically, calculator 22 calculates the third command value by using ideal model 231, control model 232, and difference suppression model 233 each stored in storage 23, which will be described later. Calculator 22 is implemented by, for example, a microcomputer, but may be implemented by a processor. The function of calculator 22 is implemented by, for example, a microcomputer, a processor, or the like executing a control program stored in storage 23. Although not illustrated in FIG. 1, calculator 22 may include a plurality of adders and subtractors in order to calculate the third command value.

Storage 23 is a storage device that stores the control program executed by calculator 22, ideal model 231, control model 232, difference suppression model 233, and the like. Storage 23 is, for example, implemented by a semiconductor memory or the like.

Ideal model 231 is a model that mathematically expresses a behavior of mounting apparatus 1 without considering the stiffness of the floor on which mounting apparatus 1 is installed. In other words, ideal model 231 is a model expressing an influence of vibration generated in machine base 12 and leg 13 on the position of mount portion 11. Note that ideal model 231 will be described in detail later.

Control model 232 is a model that converts a command for drive unit 121 to change the position of mount portion 11 to the target position into a first command value suitable for input to ideal model 231.

Difference suppression model 233 is a model that outputs a second command value for reducing, to zero, a difference between the position of mount portion 11 obtained when the first command value converted by control model 232 is input to ideal model 231 and the position of mount portion 11 when control unit 123 controls drive unit 121 on the basis of the first command value. In other words, difference suppression model 233 is a model that outputs the second command value for suppressing an influence of vibration of the floor on the position of mount portion 11, the vibration being generated by a propagation of vibration generated when the mounting apparatus mounts the electronic component on the substrate to the floor.

Calculator 22 calculates the third command value obtained by adding the second command value output from difference suppression model 233 to the first command value output from control model 232.

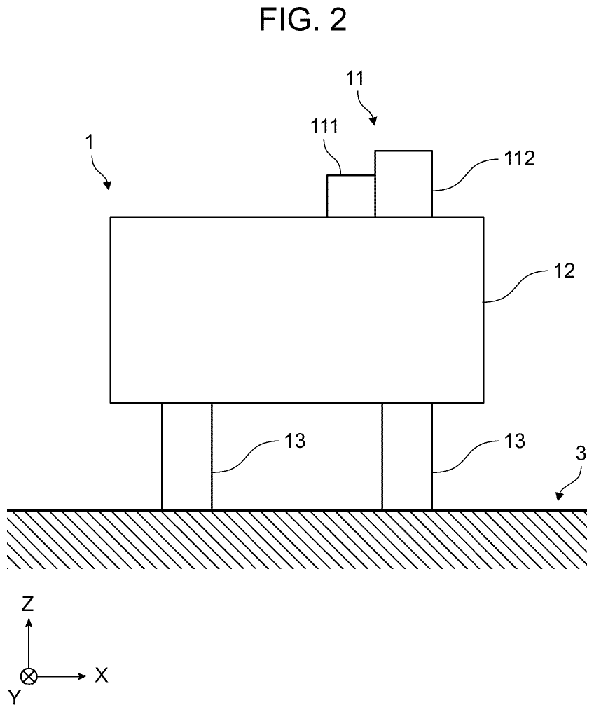

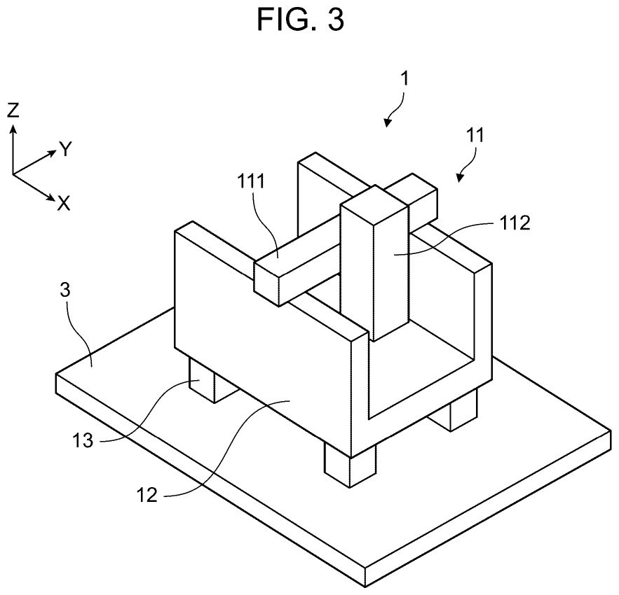

Controller 24 is a user interface unit that receives an input of a control parameter used to express difference suppression model 233 from user U. Controller 24 is implemented by, for example, a touch panel, but may include a hardware button in addition to the touch panel. Although not illustrated, control device 2 may include a display implemented by a display panel such as a liquid crystal panel or an organic electro luminescence (EL) panel, and controller 24 and the display may constitute a graphical user interface (GUI).

[Example of mounting apparatus] Hereinafter, an example of mounting apparatus 1 according to the present exemplary embodiment will be described with reference to FIGS. 2 and 3. FIG. 2 is a side view illustrating an appearance of mounting apparatus 1. FIG. 3 is a perspective view illustrating the appearance of mounting apparatus 1.

As illustrated in FIGS. 2 and 3, mounting apparatus 1 is installed on floor 3. That is, legs 13 of mounting apparatus 1 support machine base 12 of mounting apparatus 1 with respect to floor 3.

Mount portion 11 includes beam 111 and head 112.

Beam 111 is a moving mechanism for moving head 112 in a direction parallel to a Y axis (also described as a translational direction in this specification). Specifically, in order to make head 112 movable with respect to the translational direction, beam 111 is provided with a rail (corresponding to support 122) extending in a Y-axis direction (not illustrated).

Head 112 is a robot hand or the like that mounts the second member on the first member. Note that as head 112, a second member supplied from a component supply unit (not illustrated) is used.

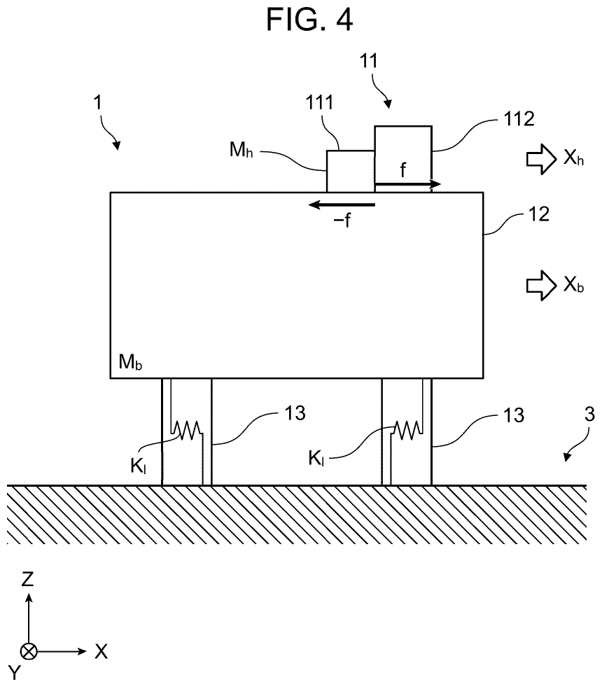

In the description of FIGS. 2 and 3, an example in which head 112 of mount portion 11 is movable only in the direction parallel to the Y axis has been described, but the present disclosure is not limited to this example. For example, head 112 may be movable in a direction parallel to an X axis by installing beam 111 in the direction parallel to the X axis, or head 112 may be movable in a direction parallel to a Z axis by installing beam 111 in the direction parallel to the Z axis. For example, mount portion 11 may include a plurality of beams 111, so that, for example, head 112 may be movable with respect to the direction parallel to the X axis and the direction parallel to the Y axis, or head 112 may be movable with respect to the direction parallel to the X axis, the direction parallel to the Y axis, and the direction parallel to the Z axis. In other words, mount portion 11 may include the plurality of beams 111 so that head 112 may be movable in any two directions or head 112 may be movable in any three directions.

[Ideal model] Ideal model 231 will be described below. FIG. 4 is a diagram schematically illustrating the behavior of mounting apparatus 1 when stiffness of floor 3 is not taken into consideration.

As illustrated in FIG. 4, first, the mass of mount portion 11 (beam 111 and head 112) is Mₕ, and the mass of machine base 12 is M_{b}. A thrust required for drive unit 121 to move the position of mount portion 11 to the target position is f. A displacement amount (that is, a movement distance of mount portion 11) of mount portion 11 obtained by applying thrust f to mount portion 11 by drive unit 121 is xₕ. Furthermore, a stiffness value of leg 13 is Kₗ.

Under such conditions, thrust f applied to mount portion 11 by drive unit 121 generates reaction force −f in machine base 12 with the same magnitude as thrust f and in a direction opposite to thrust f. When machine base 12 vibrates due to generation of reaction force −f in machine base 12, the displacement amount due to the vibration of machine base 12 is x_{b}.

When mounting apparatus 1 is regarded as a model as illustrated in FIG. 4, ideal model 231 is expressed by equation (1) including thrust f for drive unit 121 to move mount portion 11, mass Mₕ of mount portion 11, displacement amount xₕ of mount portion 11, mass M_{b} of machine base 12, displacement amount x_{b} of machine base 12, and stiffness value Kₗ of leg 13. That is, a model expression represented by equation (1) mathematically expresses the behavior of mounting apparatus 1 without considering the stiffness of floor 3.

$$\begin{matrix}[ Equation 1 ] & \\ \frac{d}{dt} {x}_{st} = A \cdot {x}_{st} + B \cdot f \\ x = C \cdot {x}_{st} \\ {x}_{st} = [ \begin{matrix}{x}_{h} \\ \cdot \\ {x}_{h} \\ {x}_{b} \\ \cdot \\ {x}_{b}\end{matrix} ] , \\ A = [ \begin{matrix}0 & 1 & 0 & 0 \\ 0 & 0 & 0 & 0 \\ 0 & 0 & 0 & 1 \\ 0 & 0 & - {K}_{l} / {M}_{b} & 0\end{matrix} ] , \\ B = {[ \begin{matrix}0 & 1 / {M}_{h} & 0 & 1 / {M}_{b}\end{matrix} ]}^{T} , \\ C = [ \begin{matrix}1 & 0 & 1 & 0\end{matrix} ] & ( 1 )\end{matrix}$$

Ideal model 231 is expressed by equation (1) including stiffness value Kₗ of leg 13. As a result, ideal model 231 can mathematically express ideal behavior of mounting apparatus 1 (that is, behavior considering only mounting apparatus 1 without considering the vibration generated in floor 3).

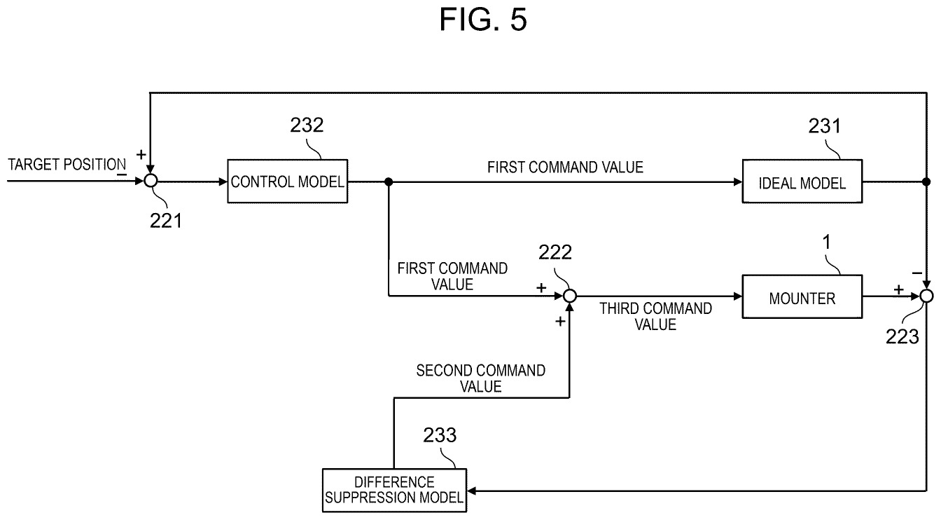

Note that since actual mount portion 11 includes a motor for moving mount portion 11, a robot hand, and the like, it is assumed that the mass of mount portion 11 as a whole is large. Therefore, in the model illustrated in FIG. 4, mass Mn of mount portion 11 cannot be ignored relative to mass M_{b} of machine base 12. It is assumed that thrust f for moving mount portion 11 becomes also large as mass Mₕ of mount portion 11 becomes large, and it is assumed that reaction force −f becomes similarly large. As a result, since it is assumed that larger vibration occurs in mounting apparatus 1 (that is, machine base 12 and leg 13), the accuracy of the model represented by equation (1) is important for improving the accuracy of positioning control.

[Control scheme of control device] Hereinafter, a flow (that is, a control scheme of control device 2) when calculator 22 generates the third command value and control unit 123 of mounting apparatus 1 controls drive unit 121 on the basis of the generated third command value will be described. FIG. 5 is a block diagram illustrating the control scheme for calculator 22 of control device 2 according to the exemplary embodiment to control mounting apparatus 1. Note that calculator 22 includes subtractor 221, adder 222, and subtractor 223 in order to implement the control scheme illustrated in FIG. 5.

First, subtractor 221 calculates a difference between the position of mount portion 11 output from ideal model 231 and the target position of mount portion 11 acquired by input and output unit 21. The difference calculated by subtractor 221 is a command for drive unit 121 to change the position of mount portion 11 to the target position.

Using control model 232, calculator 22 outputs the difference calculated by subtractor 221 as the first command value suitable for input to ideal model 231. Calculator 22 inputs the first command value output by control model 232 to ideal model 231 and outputs the position of mount portion 11. The position of mount portion 11 obtained at this time is the behavior of mounting apparatus 1 when the stiffness of floor 3 is not considered.

On the other hand, adder 222 calculates the third command value by adding the second command value output by using difference suppression model 233 to the output first command value. Then, calculator 22 outputs the calculated third command value to mounting apparatus 1 via input and output unit 21. Then, control unit 123 controls drive unit 121 on the basis of the output third command value, and outputs the current position of mount portion 11 obtained by using encoder 124 to control device 2.

Subtractor 223 calculates a difference between the position of mount portion 11 output by using ideal model 231 and the current position of mount portion 11 acquired from control device 2. The difference obtained at this time is a vibration component of floor 3 generated by propagation of reaction force −f to floor 3, the reaction force being generated in thrust f for moving mount portion 11.

Calculator 22 calculates the second command value for reducing the difference calculated by subtractor 223 to zero by using difference suppression model 233.

Such a control scheme of control device 2 enables calculation of the second command value in consideration of the stiffness of floor 3. Furthermore, control device 2 including calculator 22 that calculates the third command value obtained by adding the second command value to the first command value that is a command value for drive unit 121 to change the position of mount portion 11 to the target position can suppress the vibration of mounting apparatus 1 in consideration of the stiffness of floor 3.

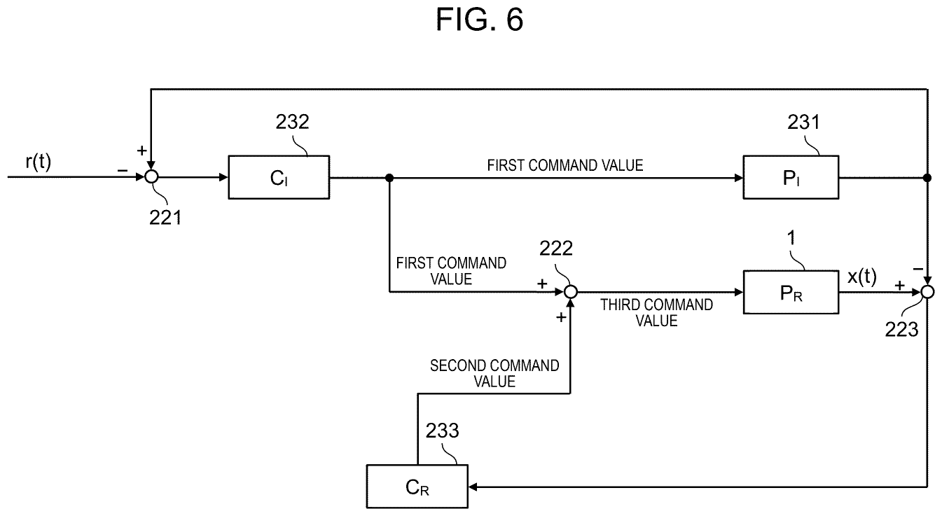

The control scheme of control device 2 illustrated in FIG. 5 can be expressed by using transfer functions. FIG. 6 is a diagram for describing the control scheme of control device 2 illustrated in FIG. 5 by using the transfer functions.

As illustrated in FIG. 6, a displacement locus (that is, the target position) for driving mount portion 11 is set to r(t), and an actual movement amount (that is, the displacement amount) of mount portion 11 is set to x(t). When a transfer function of ideal model 231 is P_{I}, a transfer function of control model 232 is C_{I}, a transfer function of difference suppression model 233 is CR, and a transfer function of mounting apparatus 1 is P_{R}, the control scheme of control device 2 is expressed by equation (2). Transfer function P_{I} of ideal model 231 is derived from equation (1). Actual movement amount x(t) of mount portion 11 corresponds to displacement amount xₕ of mount portion 11 in equation (1).

$$\begin{matrix}[ Equation 2 ] & \\ \frac{x ( t )}{r ( t )} = \frac{{C}_{I} {P}_{I}}{1 - {C}_{R} {P}_{R}} ( \frac{1 + {C}_{I} {P}_{I} - {C}_{R} {P}_{R} - {C}_{I} {P}_{R}}{1 + {C}_{I} {P}_{I}} ) & ( 2 )\end{matrix}$$

For example, when transfer function P_{I} of ideal model 231 and transfer function P_{R} of mounting apparatus 1 are the same (P_{I}=P_{R}), equation (2) is expressed by equation (3). This enables expression in the same form as a general closed loop transfer function.

$$\begin{matrix}[ Equation 3 ] & \\ \frac{x ( t )}{r ( t )} = \frac{{C}_{I} {P}_{I}}{1 - {C}_{R} {P}_{I}} ( \frac{1 + {C}_{I} {P}_{I} - {C}_{R} {P}_{I} - {C}_{I} {P}_{I}}{1 + {C}_{I} {P}_{I}} ) = \frac{{C}_{I} {P}_{I}}{1 - {C}_{R} {P}_{I}} ( \frac{1 - {C}_{R} {P}_{I}}{1 + {C}_{I} {P}_{I}} ) = \frac{{C}_{I} {P}_{I}}{1 - {C}_{I} {P}_{I}} & ( 3 )\end{matrix}$$

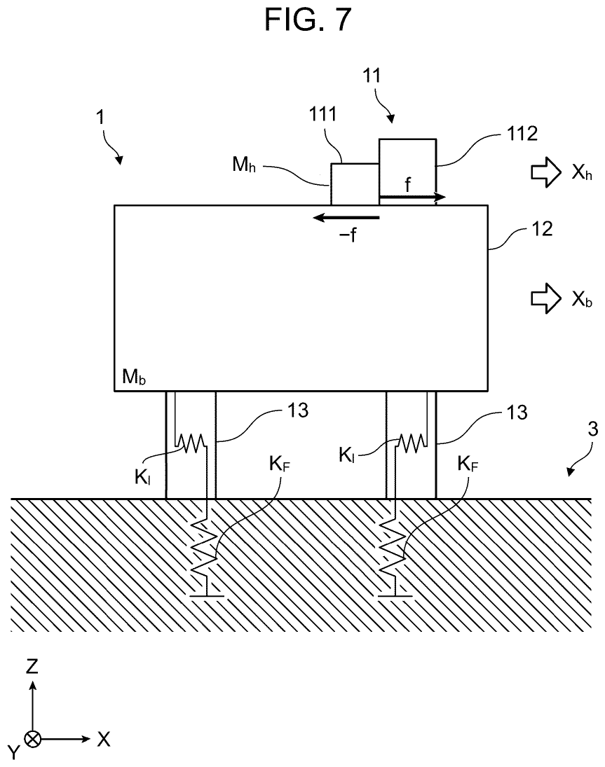

For example, when difference suppression model 233 is a model for PID control, equation (2) is expressed by equation (4).

$$\begin{matrix}[ Equation 4 ] & \\ \frac{x ( t )}{r ( t )} = \frac{{C}_{I} {P}_{I}}{1 - {C}_{R} {P}_{R}} ( \frac{1 + {C}_{I} {P}_{I} - {C}_{R} {P}_{R} - {C}_{I} {P}_{R}}{1 + {C}_{I} {P}_{I}} ) = \frac{{C}_{I} {P}_{I}}{1 - ( P + \frac{I}{s} + sD ) {P}_{R}} ( \frac{1 + {C}_{I} {P}_{I} - ( P + \frac{I}{s} + sD ) {P}_{R} - {C}_{I} {P}_{R}}{1 + {C}_{I} {P}_{I}} ) & ( 4 )\end{matrix}$$

[Behavior of mounting apparatus] Hereinafter, the difference calculated by subtractor 223 of calculator 22 will be described with reference to FIG. 7. FIG. 7 is a diagram schematically illustrating the behavior of mounting apparatus 1 when the stiffness of floor 3 is taken into consideration. That is, FIG. 7 is a schematic diagram illustrating the influence of the vibration generated when mounting apparatus 1 is driven at the actual installation site. The schematic diagram illustrated in FIG. 7 is different from the schematic diagram illustrated in FIG. 4 in that stiffness value K_{F} of floor 3 is shown.

As illustrated in FIG. 7, when thrust f for moving mount portion 11 is applied, reaction force −f is generated, and machine base 12 and leg 13 are deformed by reaction force −f. The force transmitted by the deformation of leg 13 is transmitted to floor 3 to generate vibration of floor 3.

In FIG. 7, the stiffness of floor 3 is expressed as spring constant K_{F} (stiffness value K_{F} of floor 3). The stiffness of floor 3 acts perpendicularly to the force transmitted by the deformation of leg 13. In other words, the stiffness of floor 3 can be regarded as a spring in a direction parallel to a Z-axis direction.

The vibration generated in floor 3 propagates through legs 13 and machine base 12 of mounting apparatus 1, and affects the positioning control of mount portion 11.

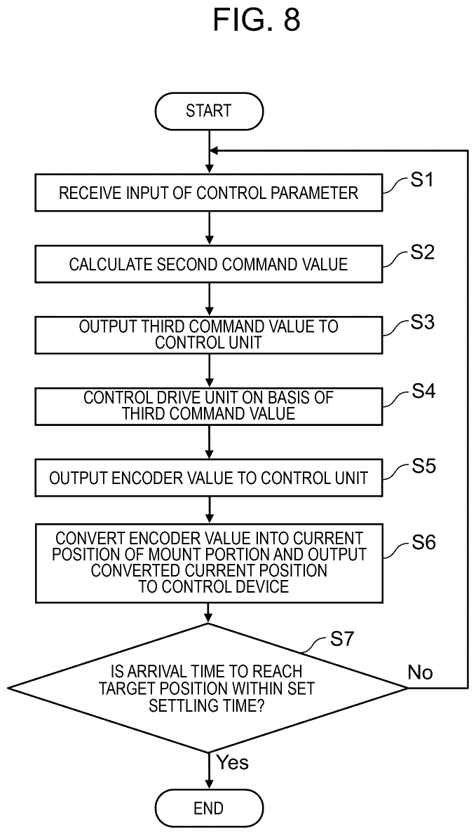

As described above, the difference between the schematic diagram illustrated in FIG. 4 and the schematic diagram illustrated in FIG. 7 is that stiffness value K_{F} of floor 3 is shown. That is, the difference between the schematic diagram illustrated in FIG. 4 and the schematic diagram illustrated in FIG. 7 is whether the stiffness of floor 3 is taken into consideration or not. Therefore, this difference is expressed as the difference calculated by subtractor 223 of calculator 22 in the description of FIG. 5 (that is, a difference between the position of mount portion 11 to be output by using ideal model 231 and the current position of mount portion 11 acquired from control device 2). Since calculator 22 calculates the second command value for reducing the difference calculated by subtractor 223 to zero by using difference suppression model 233, control device 2 can suppress the vibration of mounting apparatus 1 in consideration of the stiffness of floor 3.

[Adjustment method of control device] FIG. 8 is a flowchart illustrating an operation for tuning the control parameter for expressing difference suppression model 233 (that is, adjustment method of control device 2).

First, controller 24 receives an input of the control parameter for expressing difference suppression model 233 (S1).

Calculator 22 sets the control parameter received in step S1 in difference suppression model 233, and calculates the second command value by using difference suppression model 233 (S2). Then, calculator 22 adds the second command value calculated in step S2 to the first command value to generate the third command value, and outputs the generated third command value to control unit 123 (S3).

Control unit 123 controls drive unit 121 on the basis of the third command value output in step S3 (S4). Encoder 124 calculates an encoder value on the basis of, for example, the displacement amount of drive unit 121 in step S4, and outputs the calculated encoder value to control unit 123 (S5). Then, control unit 123 converts the encoder value output in step S5 into the position of mount portion 11, and outputs the converted current position of mount portion 11 to control device 2 (S6).

Calculator 22 calculates an arrival time from the position of mount portion 11 output in step S6 to the target position, and determines whether the calculated arrival time is within a set settling time (S7). The set settling time is a settling time desired by the user.

When it is determined that the calculated arrival time is not within the set settling time (No in S7), calculator 22 executes the processing of step S1 again.

When it is determined that the calculated arrival time is within the set settling time (Yes in S7), calculator 22 ends the tuning of the control parameter for expressing difference suppression model 233.

As a result, control device 2 can receive the input of the control parameter used to express difference suppression model 233 from user U via controller 24. That is, after mounting apparatus 1 is installed in an actual site such as a factory, control device 2 can tune (adjust) difference suppression model 233 in accordance with the stiffness of floor 3 in a place where mounting apparatus 1 is installed. Therefore, control device 2 can more effectively suppress the vibration of mounting apparatus 1 after adjusting difference suppression model 233 suitable for the environment in which mounting apparatus 1 is actually used.

In step S7, an example has been described in which calculator 22 uses the settling time until the vibration of mounting apparatus 1 converges as an index of determination, but the present disclosure is not limited to this example.

The adjustment method of control device 2 illustrated in FIG. 8 is an example in which user U tunes the control parameter, but the present disclosure is not limited to this example. For example, when control device 2 has an auto-tuning function based on a control theory, an optimal control parameter is determined by setting a settling time, a vibration width, or the like input by user U as a target value and then operating mounting apparatus 1 a plurality of times. Control device 2 may display a combination of the control parameter and an operation result when mounting apparatus 1 is operated with the control parameter on a display screen, and let user U determine which control parameter to be set in difference suppression model 233.

Control device 2 may use a trained deep learning model in tuning of the control parameter. For example, control device 2 outputs the optimum control parameter by inputting the position command value, the control parameter, the displacement locus of drive unit 121 when mounting apparatus 1 is actually operated, the settling time, and the like to the deep learning model, and sets the control parameter to difference suppression model 233.

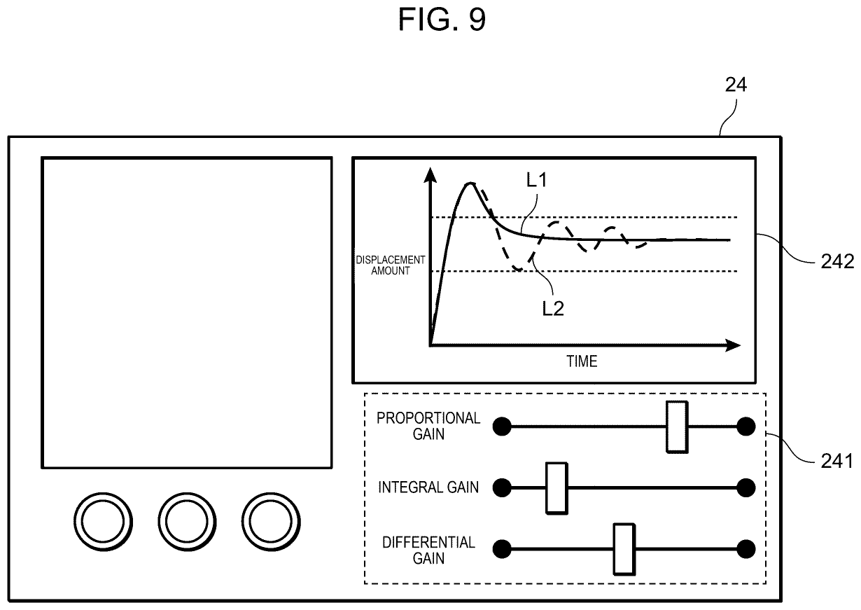

FIG. 9 is a diagram illustrating an example of controller 24 when receiving the input of the control parameter in step S1 of FIG. 8. That is, user U tunes the control parameter by using controller 24 illustrated in FIG. 9.

As illustrated in FIG. 9, controller 24 includes control parameter input reception area 241 and adjustment result display area 242.

The control parameter input reception area 241 includes sliders. In the example of FIG. 9, user U adjusts a proportional gain, an integral gain, and a derivative gain, which are control parameters, with the sliders.

Adjustment result display area 242 is a display screen that displays the adjustment result of the control parameters. In the example of FIG. 9, in adjustment result display area 242, the displacement amount of drive unit 121 is displayed, and waveform data L1 before adjustment of the control parameter and waveform data L2 after adjustment of the control parameter are displayed. User U can tune the control parameters by comparing waveform data L1 and waveform data L2 displayed in adjustment result display area 242.

In FIG. 9, the control parameters indicated in control parameter input reception area 241 are control parameters used in the PID control. However, the control parameters are not limited to general PID control including a proportional gain, an integral gain, and a derivative gain, and control parameters used in other control schemes may be displayed. For example, control parameters used in PI control or PD control may be displayed in control parameter input reception area 241.

A parameter related to any one of PID control, PI control, or PD control to which at least one of an anti-windup function or an output restriction function is added may be displayed in control parameter input reception area 241. The anti-windup function is a control method for stopping an integration operation when the output of the controller is different from the input to the actual system. The output restriction function is, for example, a control method of preventing hunting in which overshoot and undershoot are repeated in the output by setting a dead zone for the input to control unit 123.

The control parameters used in on/off control may be displayed in control parameter input reception area 241. For example, when the on/off control is adopted, it is possible to employ a simple control scheme in which the number of control parameters that require adjustment is smaller than in the PID control. The on/off control is a control method for outputting a constant command value by switching the output from control unit 123 on or off with reference to whether a set threshold is exceeded for the input to control unit 123 or not.

In the present exemplary embodiment, a case in which difference suppression model 233 is for the PID control has been described. Alternatively, difference suppression model 233 may be for the other control schemes. For example, any one of the on/off control, the PD control, the PI control, or the PID control can be applied as a control scheme targeted by difference suppression model 233. First, when the on/off control is applied, there is an advantage that a significantly simple control scheme is used, but there is a disadvantage that hunting is likely to occur. When the hunting occurs due to the application of the on/off control, for example, the PD control is applied next. However, when the PD control is applied, there is a possibility that a control deviation cannot be resolved. Therefore, when the control deviation cannot be resolved because the PD control is applied, for example, the PID control is applied.

From the above description, control device 2 according to the present exemplary embodiment has the following advantages. Control device 2 including storage 23 that stores ideal model 231 that mathematically expresses the behavior of mounting apparatus 1 without considering the stiffness of floor 3 can calculate, by using ideal model 231, the position of mount portion 11 when only the vibration in machine base 12 and leg 13 affects the behavior of mounting apparatus 1. Control device 2 includes storage 23 that stores difference suppression model 233 that calculates the second command value for reducing, to zero, the difference between the position of mount portion 11 obtained when the first command value is input to ideal model 231 and the position of mount portion 11 when control unit 123 controls drive unit 121 on the basis of the first command. In other words, the difference between the position of mount portion 11 obtained when the first command value is input to ideal model 231 and the position of mount portion 11 when control unit 123 controls drive unit 121 on the basis of the first command is a difference obtained by the influence of the vibration of floor 3 generated by the propagation of vibration to floor 3 generated when mounting apparatus 1 mounts the second member on the first member. Therefore, control device 2 can calculate the second command value in consideration of the stiffness of floor 3 by using difference suppression model 233. Furthermore, control device 2 including calculator 22 that outputs the third command value obtained by adding the second command value to the first command value to control unit 123 can cause control unit 123 to control drive unit 121 on the basis of such a third command value. Therefore, control device 2 can suppress the vibration of mounting apparatus 1 in consideration of the stiffness of floor 3.

### Other Exemplary Embodiments

While the control device and the like according to the present disclosure have been described above on the basis of the exemplary embodiment, the present disclosure is not limited to the exemplary embodiment. The present exemplary embodiment and modifications to which various changes conceivable by those skilled in the art are applied, or another form constructed by combining some components in the exemplary embodiment is also included in the scope of the present disclosure without departing from the gist of the present disclosure.

For example, the processing executed by a specific processing unit in the above exemplary embodiment may be executed by another processing unit. The order of a plurality of pieces of processing may be changed, or a plurality of pieces of processing may be executed in parallel.

For example, the order of the processing described in the flowchart of the above exemplary embodiment is an example. The order of the plurality of processing may be changed, or the plurality of processing may be executed in parallel.

In addition, general or specific aspects of the present disclosure may be realized by a system, a device, a method, an integrated circuit, a computer program, or a computer-readable recording medium such as a CD-ROM. A general or specific mode of the present disclosure may be implemented by any combination of a system, a device, a method, an integrated circuit, a computer program, and a recording medium.

The present disclosure may be achieved as a control method executed by a computer, or may be achieved as a program for causing a computer to execute such a control method. The present disclosure may be achieved as a computer-readable non-transitory recording medium in which such a program is recorded.

The present disclosure provides the control device and the like that can accurately suppress the vibration of the mounting apparatus in consideration of the stiffness of the floor.

The control device and the like according to the present disclosure can be used as a control device and the like that controls a mounting apparatus that mounts an electronic component on a substrate.

What is claimed is:

1. A control device that controls a mounting apparatus including: a drive unit that changes a position of a mount portion that mounts a second member on a first member; a control unit that controls the drive unit; a machine base that accommodates the drive unit and the control unit; and a leg that is connected to the machine base and supports the machine base with respect to a floor, the control device comprising:
a storage that stores
an ideal model that mathematically expresses a behavior of the mounting apparatus without considering stiffness of the floor,
a control model that converts a command for the drive unit to change the position of the mount portion to a target position into a first command value suitable for input to the ideal model, and
a difference suppression model that outputs a second command value for reducing, to zero, a difference between the position of the mount portion obtained when the first command value is input to the ideal model and the position of the mount portion when the control unit controls the drive unit based on the first command value; and
a calculator that calculates a third command value obtained by adding the second command value to the first command value and outputs the third command value to the control unit, wherein
the control unit controls the drive unit based on the third command value that has been output.

2. The control device according to claim 1, wherein
the ideal model is defined by the following equation:
$$\begin{matrix}[ Equation 1 ] & \\ \frac{d}{dt} {x}_{st} = A \cdot {x}_{st} + B \cdot f \\ x = C \cdot {x}_{st} \\ {x}_{st} = [ \begin{matrix}{x}_{h} \\ \cdot \\ {x}_{h} \\ {x}_{b} \\ \cdot \\ {x}_{b}\end{matrix} ] , \\ A = [ \begin{matrix}0 & 1 & 0 & 0 \\ 0 & 0 & 0 & 0 \\ 0 & 0 & 0 & 1 \\ 0 & 0 & - {K}_{l} / {M}_{b} & 0\end{matrix} ] , \\ B = {[ \begin{matrix}0 & 1 / {M}_{h} & 0 & 1 / {M}_{b}\end{matrix} ]}^{T} , \\ C = [ \begin{matrix}1 & 0 & 1 & 0\end{matrix} ] & \end{matrix}$$
and the ideal model includes a mass Mₕ of the mount portion, a displacement amount xₕ of the mount portion, a mass M_{b} of the machine base, a displacement amount x_{b} of the machine base, and a stiffness value Kₗ of the leg.

3. The control device according to claim 1, wherein
the second command value calculated by the calculator is a command value for suppressing vibration of the mounting apparatus caused by the stiffness of the floor.

4. The control device according to claim 1, further comprising:
a controller that receives an input of a control parameter used to express the difference suppression model, wherein
the difference suppression model outputs the second command value based on the control parameter having been received.

5. The control device according to claim 4, wherein
the control parameter is at least one of a proportional gain, an integral gain, or a derivative gain in PID control, PI control, or PD control.

6. The control device according to claim 4, wherein
the control parameter is a parameter related to any one of on/off control or one of the PID control, the PI control, or the PD control to which at least one function of an anti-windup function or an output restriction function is added.

7. The control device according to claim 1, wherein
the control unit controls a current applied to the drive unit based on the third command value that has been output.

8. A control method executed by a computer that controls a mounting apparatus including: a drive unit that changes a position of a mount portion that mounts a second member on a first member; a control unit that controls the drive unit; a machine base that accommodates the drive unit and the control unit; a leg that is connected to the machine base and supports the machine base with respect to a floor; and a storage that stores: an ideal model that mathematically expresses a behavior of the mounting apparatus without considering stiffness of the floor; a control model that converts a command value for the drive unit to change the position of the mount portion to a target position into a first command value suitable for input to the ideal model; and a difference suppression model that outputs a second command value for reducing, to zero, a difference between the position of the mount portion obtained when the first command value is input to the ideal model and the position of the mount portion when the control unit controls the drive unit based on the first command value,
the control method comprising a calculation step of calculating a third command value obtained by adding the second command value to the first command value and outputting the third command value to the control unit, wherein
the control unit controls the drive unit based on the third command value that has been output.

9. A program for causing a computer to execute the control method according to claim 8.
